(19) United States
(12) Patent Application Publication
(10) Pub. No.: US 2026/0225171 A1
(43) Pub. Date: Aug. 6, 2026

(54) OVENS FOR EQUIPMENT SUCH AS DIE ATTACH SYSTEMS, FLIP CHIP BONDING SYSTEMS, CLIP ATTACH SYSTEMS, AND RELATED METHODS

(71) Applicant: Christoph Benno Luechinger, Irvine, CA (US)

(72) Inventor: Christoph Benno Luechinger, Irvine, CA (US)

(73) Assignee: Kulicke and Soffa Industries, Inc., Fort Washington, PA (US)

(21) Appl. No.: 19/405,701

(22) Filed: Dec. 2, 2025

Related U.S. Application Data
(60) Provisional application No. 63/729,685, filed on Dec. 9, 2024.

(51) Int. Cl. B23K 1/008; B23K 101/40; F27B 17/00; F27D 1/18; F27D 7/06; F27D 9/00; H10W 72/00

(52) U.S. Cl. CPC B23K 1/008; F27B 17/0025; F27D 1/1808; F27D 7/06; F27D 9/00; H10W 72/07141; B23K 2101/40; F27D 2001/1825; F27D 2007/066; F27D 2009/0002

(57) ABSTRACT

An oven for assisting in conductive joint formation related to a workpiece is provided. The oven includes a vacuum chamber. The vacuum chamber is configured to receive the workpiece. The vacuum chamber includes (i) a body portion and (ii) a cover configured to cover the body portion. The body portion defines a groove configured to receive a sealing structure for creating a seal between the cover and the body portion. The body portion defines a cooling channel configured to receive a cooling fluid for cooling the groove.

### CROSS-REFERENCE TO RELATED APPLICATION

This application claims the benefit of U.S. Provisional Application No. 63/729,685, filed Dec. 9, 2024, the content of which is incorporated herein by reference.

### FIELD

The invention relates to ovens for equipment such as die attach systems, flip chip bonding systems, clip attach systems, and related methods.

### BACKGROUND

In the electronics assembly industry (e.g., including die attach, flip chip bonding, clip attach, etc.), connections including solder material are often used. For example, in certain conventional die attach applications, soft solder interconnections may be used. In other examples, in certain clip attach applications, solder reflow interconnections may be used.

In connection with such die attach and clip attach applications, an oven may be used in the interconnection process (e.g., in connection with the solder reflow process).

There are many factors to consider when designing such ovens. For example: processing time of workpieces (e.g., units per hour); temperature control as workpieces move through the oven; accessibility of the components of the oven (e.g., for maintenance, cleaning, etc.); among others. U.S. Pat. No. 11,465,224 illustrates exemplary designs related to such ovens, and is incorporated herein by reference in its entirety.

In particular, vacuum chambers present design, operational, and maintenance challenges in connection with such ovens.

Thus, it would be desirable to provide improved ovens, and related equipment and processes, for use in the electronics assembly industry.

### SUMMARY

According to an exemplary embodiment of the invention, an oven for assisting in conductive joint formation related to a workpiece is provided. The oven includes a vacuum chamber. The vacuum chamber is configured to receive the workpiece. The vacuum chamber includes (i) a body portion and (ii) a cover configured to cover the body portion. The body portion defines a groove configured to receive a sealing structure for creating a seal between the cover and the body portion. The body portion defines a cooling channel configured to receive a cooling fluid for cooling the groove.

According to other embodiments of the invention, the oven recited in the immediately preceding paragraph may have any one or more of the following features: the sealing structure is a gasket; the body portion is configured to be removed from the oven; the body portion is a removable insert; the body portion includes a heat plate for heating the workpiece; a motor operably coupled to the cover, the cover being configured to be moved in at least one direction by the motor; the motor is configured to move the cover in the at least one direction between a closed position and an open position; a vacuum source configured to pull a vacuum in the vacuum chamber when the cover is in the closed position, wherein the vacuum in the vacuum chamber results in the cover moving further downward from the closed position; the cooling channel is disposed along a path adjacent the groove; the path includes a loop shape, an inlet path connected to the loop shape, and an outlet path connected to the loop shape; and an oven chamber, the vacuum chamber being positioned within the oven chamber, the oven chamber being at least partially defined by (i) an oven plate and (ii) an oven cover.

According to another exemplary embodiment of the invention, an oven for assisting in conductive joint formation related to a workpiece is provided. The oven includes a vacuum chamber. The vacuum chamber is configured to receive the workpiece. The vacuum chamber includes (i) a body portion and (ii) a cover configured to cover the body portion. The oven also includes a motion system configured to move the cover with respect to the body portion between an open position and a closed position. The oven also includes a vacuum source configured to pull a vacuum in the vacuum chamber, the vacuum source sealing the cover against the body portion when the cover is in the closed position.

According to other embodiments of the invention, the oven recited in the immediately preceding paragraph may have any one or more of the following features: in the closed position, when the vacuum source pulls the vacuum, the cover moves closer to the body portion for sealing the cover against the body portion; the body portion defines a groove configured to receive a sealing structure for creating a seal between the cover and the body portion, when the vacuum source pulls a vacuum to form the seal, the sealing structure compresses and moves the cover between a range of 0.2-2.0 mm; the motion system includes a plurality of rods coupled to the cover; the motion system includes thermal expansion structures coupled to each of the plurality of rods; and the cover has a range of motion between the open position and the closed position of between 10-200 mm.

According to another exemplary embodiment of the invention, an oven for assisting in conductive joint formation related to a workpiece is provided. The oven includes a vacuum chamber. The vacuum chamber is configured to receive the workpiece. The vacuum chamber includes (i) a body portion and (ii) a cover configured to cover the body portion. The oven also includes a flux removal system for removing flux from the vacuum chamber.

According to other embodiments of the invention, the oven recited in the immediately preceding paragraph may have any one or more of the following features: the flux removal system is disposed along a lower surface of the body portion; the flux removal system includes an aperture for draining the flux from the vacuum chamber, and a valve for selectively allowing the flux to pass through the aperture; the body portion defines a collection region for collecting the flux to be removed from the vacuum chamber; a nitrogen supply to provide nitrogen (or another inert gas or active gas mixture such as a nitrogen hydrogen mix, e.g., with a hydrogen content not exceeding 5.7%) to the vacuum chamber; during operation of the flux removal system the body portion is held at a temperature which keeps the flux in a liquid state; the temperature is between 80-120° C.; further including a thermocouple for sensing the temperature; and the body portion defines a groove configured to receive a sealing structure for creating a seal between the cover and the body portion, the body portion defines a cooling channel configured to receive a cooling fluid for cooling the groove.

According to another exemplary embodiment of the invention, a method of operating an oven for assisting in conductive joint formation related to a workpiece is provided. The method includes the steps of: (a) closing a cover of a vacuum chamber of the oven with respect to a body portion of the vacuum chamber, the body portion defining a groove configured to receive a sealing structure for creating a seal between the cover and the body portion when the cover is closed; and (b) cooling the groove by flowing a cooling fluid through a cooling channel defined by the body portion.

According to other embodiments of the invention, the method recited in the immediately preceding paragraph may have any one or more of the following features: the sealing structure is a gasket; step (a) includes moving the cover from an open position to a closed position with a motor operably coupled to the cover; step (a) includes pulling a vacuum in the vacuum chamber when the cover is in the closed position; the cover moves downward from the closed position when the vacuum is pulled in the vacuum chamber; the cooling channel is disposed along a path adjacent the groove; and the path includes a loop shape, an inlet path connected to the loop shape, and an outlet path connected to the loop shape.

According to another exemplary embodiment of the invention, a method of operating an oven for assisting in conductive joint formation related to a workpiece is provided. The method includes the steps of: (a) providing a vacuum chamber in the oven, the vacuum chamber configured to receive the workpiece, the vacuum chamber including (i) a body portion and (ii) a cover configured to cover the body portion; (b) moving the cover with respect to the body portion from an open position to a closed position; and (c) pulling a vacuum in the vacuum chamber to seal the cover against the body portion when the cover is in the closed position.

According to other embodiments of the invention, the method recited in the immediately preceding paragraph may have any one or more of the following features: the body portion defines a groove configured to receive a sealing structure for creating a seal between the cover and the body portion when the cover is in the closed position, and when the vacuum is pulled in the vacuum chamber in step (c), a vacuum seal is formed (e.g., with the sealing structure); step (c) causes compression of the sealing structure and moves the cover between a range of 0.2-2.0 mm; step (c) includes moving the cover closer to the body portion for sealing the cover against the body portion using the vacuum; step (b) includes moving the cover from the open position to the closed position with a motor operably coupled to the cover; and step (b) includes moving the cover in a range of motion of between 10-200 mm.

According to another exemplary embodiment of the invention, a method of operating an oven for assisting in conductive joint formation related to a workpiece is provided. The method includes the steps of: (a) providing a vacuum chamber of the oven, the vacuum chamber configured to receive the workpiece, the vacuum chamber including (i) a body portion and (ii) a cover configured to cover the body portion; and (b) removing flux from the vacuum chamber using a flux removal system of the vacuum chamber.

According to other embodiments of the invention, the method recited in the immediately preceding paragraph may have any one or more of the following features: the flux removal system is disposed along a lower surface of the body portion; step (b) includes removing flux from the vacuum chamber through an aperture for draining the flux from the vacuum chamber by operating a valve for selectively allowing the flux to pass through the aperture; a step of collecting flux in a collection region of the body portion for collecting the flux to be removed from the vacuum chamber in step (b); a step of providing nitrogen to the vacuum chamber from a nitrogen supply (or another inert gas or active gas mixture such as a nitrogen hydrogen mix, e.g., with a hydrogen content not exceeding 5.7%); during operation of the flux removal system the body portion is held at a temperature which keeps the flux in a liquid state; the temperature is between 80-120° C.; a step of sensing the temperature using a thermocouple; and the body portion defines a groove configured to receive a sealing structure for creating a seal between the cover and the body portion, the body portion defines a cooling channel, the method including a step of flowing a cooling fluid through the cooling channel for cooling the groove.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1A is a block diagram top view of an oven plate of an oven for assisting in conductive joint formation related to a workpiece in accordance with various exemplary embodiments of the invention;

FIG. 1B is a block diagram cross-sectional side view of the oven of FIG. 1A;

FIG. 2 is a block diagram cross-sectional side view of a portion of the oven of FIG. 1A including a vacuum chamber;

FIG. 3A is a block diagram top view of a body portion of the vacuum chamber of FIG. 2;

FIG. 3B is a cross-sectional side view of the body portion of FIG. 3A;

FIGS. 4A-4E are a series of block diagram cross-sectional side views of a portion of the oven of FIG. 1A; and

FIG. 5 is a flow diagram of a method of operating an oven for assisting in conductive joint formation related to a workpiece in accordance with various exemplary embodiments of the invention.

### DETAILED DESCRIPTION

Aspects of the invention relate to ovens for assisting in conductive joint formation processes for a workpiece. There are many types of applications where such an oven would be useful. For example, the conductive joint formation process may be in connection with a die attach system, a flip chip bonding system, a clip attach system (which may include a die attach system, a flip chip bonding system, etc.), and similar systems in the electronics assembly industry.

The conductive joint formation process may include, for example, at least one of a sintered coupling process and a soldered coupling process (e.g., a solder reflow coupling process). Other conductive joint formation processes are contemplated.

The workpieces that undergo such a conductive joint formation process in an oven may vary widely. For example, a workpiece may include (i) a plurality of semiconductor elements (e.g., die), (ii) a substrate, and (iii) a plurality of conductive clips configured to provide conductive coupling between ones of the plurality of semiconductor elements and the substrate using a solder reflow process in the oven. In another example, the workpiece may include (i) a plurality of semiconductor elements, and (ii) a plurality of conductive clips configured to be conductively coupled to respective ones of the plurality of semiconductor elements using a solder reflow process in the oven. In yet another example, the workpiece may include (i) a semiconductor element, and (ii) a substrate, and (iii) at least one conductive clip configured to provide conductive coupling between the semiconductor element and the substrate using a solder reflow process in the oven. In yet another example, the workpiece may include (i) a semiconductor element, and (ii) at least one conductive clip configured to be conductively coupled to the die using a solder reflow process in the oven. In yet another example, the workpiece may include a plurality of die and a substrate, the plurality of die being configured to be conductively coupled to the substrate using a solder reflow process in the oven. In yet another example, the workpiece may include a semiconductor element and a substrate, the semiconductor element being configured to be conductively coupled to the substrate using solder reflow in the oven. Other types of workpieces (and conductive connections) are contemplated.

Aspects of the invention relate to ovens (and methods of operating the same) that achieve desirable pressure and temperature control for a wide range of pressure and temperature profiles to optimally support solder reflow processes.

Aspects of the invention are particularly useful in connection with applications that implement solder reflow under vacuum to improve the solder layer integrity by reducing void content significantly. While only a specific portion of a solder reflow process occurs under vacuum, the entire workpiece is typically under vacuum at the same time. To have all parts of a workpiece encounter the same temperature profile along the rest of the oven, a profile desirably has a “stair-step” shape, with a temperature desirably within ±5° C. in the step area, which must have a length equal to the width of at least one workpiece (e.g., a lead frame), and a sharp transition in between.

Solder paste reflow quality in die or clip attach regarding voiding can be improved by applying a vacuum step while the solder is liquid (i.e., while the temperature of a workpiece is above the liquidus temperature of the solder alloy used in such a workpiece). Gas bubbles can be enlarged to a larger size caused by a pressure change in the solder voids due to low ambient pressure inside a vacuum chamber according to the Young-Laplace Equation and the Ideal Gas Law. This increases the likelihood that (a) individual smaller voids combine inside the solder layer and (b) more of the solder voids reach the edge of the semiconductor element or move to the edge of the semiconductor element to allow the gas inside the void to escape, leading to the elimination or minimization of voids, especially larger voids.

Enabling a pressure level drop to a level sufficiently close to vacuum requires a vacuum chamber that can be evacuated effectively (e.g., without leakage). Certain applications benefit from a vacuum chamber that is part of an oven that can provide a vacuum while solder on a workpiece is heated (according to a solder material specific temperature profile) in a sufficiently oxygen free atmosphere.

Continuous operation of an oven typically involves repetitive opening and closing of the vacuum chamber, with a defined cycle time, without stops or interruptions. In order to achieve the necessary vacuum level, the vacuum chamber needs to be sufficiently sealed. The sealing mechanism may desirably be reliably opened and closed with appropriate repeatable sealing to enable a desired vacuum level. The operating temperature of an oven can be set up to 450° C., outside and inside the vacuum chamber, causing high temperatures of the sealing structure, requiring sealing structures (e.g., O-rings) made from materials which are capable to withstand such high temperatures for an extended time, for reliable high volume production conditions (e.g., 24/7 operation). Such materials may be expensive. Because the sealing structure (e.g., O-ring) is part of a mechanical system that opens and closes repeatedly (e.g., every 30 seconds), an expensive sealing structure may become a costly consumable and a significant cost factor in a vacuum reflow oven operation.

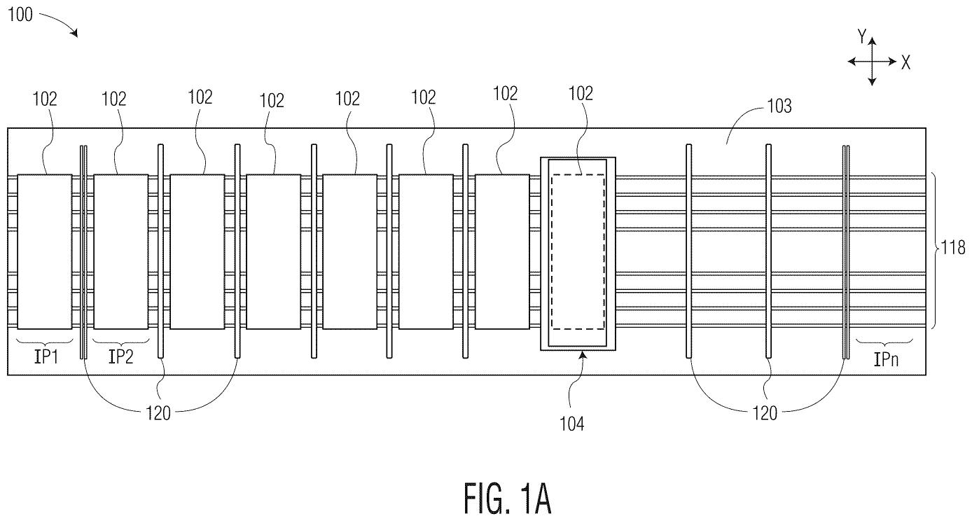

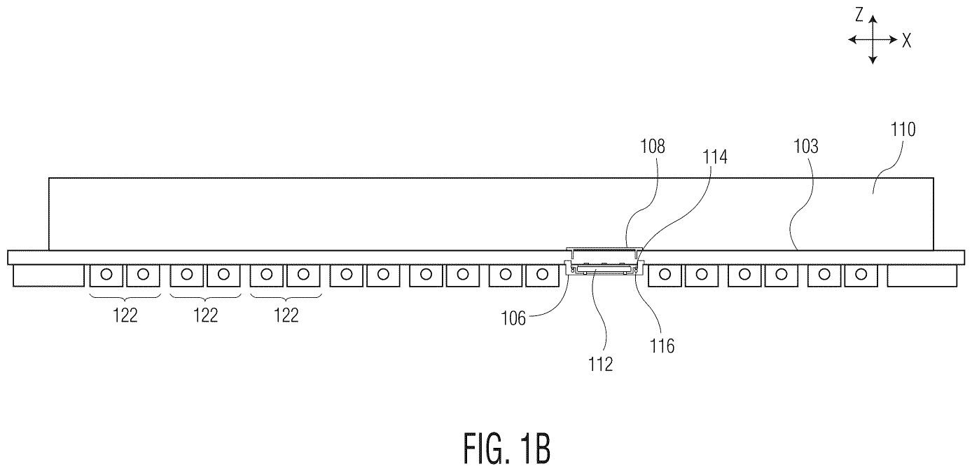

Referring now to the drawings, FIGS. 1A-1B illustrate an oven 100 (including an oven plate 103) for assisting in conductive joint formation related to a workpiece 102. Oven 100 includes a vacuum chamber 104. Vacuum chamber 104 includes a body portion 106 and a cover 108 configured to cover body portion 106. When body portion 106 and cover 108 are in contact, an enclosed space is formed for treating workpiece 102 within (e.g., using a heat plate 112, a heater block, etc.). Vacuum chamber 104 is configured to receive workpiece 102 as workpiece 102 moves along the length of oven 100 (i.e., along the X-axis).

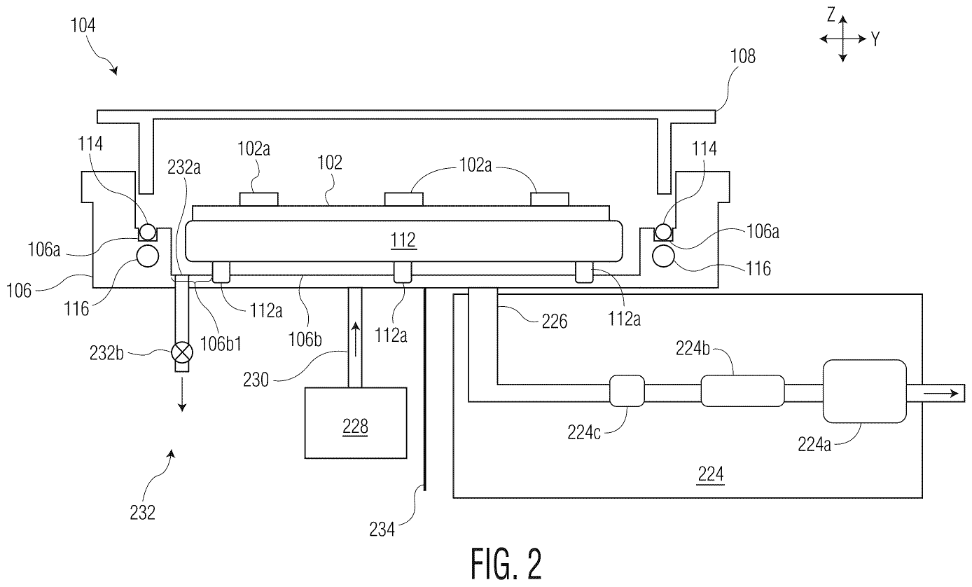

Body portion 106 defines a groove (see groove 106a of FIG. 2) configured to receive a sealing structure 114 (e.g., a gasket, an O-ring, etc.) for creating a seal between cover 108 and body portion 106. Once sealed, a vacuum source (e.g., see vacuum source 224 in FIG. 2) may pull a vacuum in order to improve conductive joint formation (e.g., to assist in the removal of voids such as gas bubbles). Body portion 106 defines a cooling channel 116 configured to receive a cooling fluid for cooling the groove. In certain embodiments, body portion 106 is configured to be removed from oven 100. For example, body portion 106 may be a removable insert to be removed from oven 100. Such a removable configuration provides improvements over the art in terms of maintenance (e.g., ability to remove byproducts of conductive joint formation).

Oven 100 is illustrated including a material handling system 118 for moving (e.g., indexing) workpiece 102 along the X-axis of oven 100 (see FIG. 1A). As illustrated, a plurality of workpieces 102 have been indexed along a plurality of indexing positions (e.g., indexing positions IP1, IP2, . . . IPn, etc.). Each indexing position is separated by a plurality of insulation structures 120 (e.g., thermal insulation structures, grooves, etc.). The outermost insulation structures 120 may be more insulative than inner insulation structures 120. For example, the outermost insulation structures 120 may include more insulation grooves to provide greater insulation (e.g., as workpieces 102 enter and/or exit oven 100). Accordingly, each indexing position can define a temperature zone for improved temperature control of workpiece 102 as it is moved along the X-axis by material handling system 118.

As each of workpieces 102 are indexed along the X-axis of oven 100, a plurality of heater blocks 122 locally heat the oven plate which heats workpiece 102. The plurality of heater blocks 122 in combination with an oven cover 110 (not illustrated in FIG. 1A) can be used to provide a controlled temperature profile as each of workpieces 102 are indexed. As illustrated, two heating blocks 122 (that may be independently controlled, from each other, and from other heating blocks 122 included in oven 100) are provided beneath each of the plurality of indexing positions/temperature zones (excluding the temperature zones of vacuum chamber 104). It should be noted that, if desired, the first zone (corresponding to indexing position IP1) and the last zone (corresponding to indexing position IPn) may not be heated, and in fact, may be actively cooled. Other variations are contemplated.

Referring now to FIG. 2, various portions of oven 100, including a vacuum chamber 104, are illustrated. Vacuum chamber 104 is configured to control the temperature of sealing structure 114 at a low level relative to the operational temperatures of heat plate 112. Body portion 106 of vacuum chamber 104 may be locally cooled by flowing a cooling fluid (e.g., water, air, etc.) through cooling channel 116 disposed adjacent groove 106a. The cooling fluid flow rate may be controlled and the thermal effects may be monitored by measuring the temperature of body portion 106 (e.g., using a thermocouple). For example, sealing structure 114 (e.g., an O-ring) disposed within groove 106a may be continuously held at a temperature that is low enough to allow using sealing structure 114 (e.g., an O-ring) that is only rated for “medium” temperatures (e.g., 205° C.). Such O-rings may be more readily available and at a relatively low cost relative to high temperature O-rings.

Referring to FIG. 2, vacuum chamber 104 is illustrated in an “open” position (e.g., a semi-open position). Vacuum chamber 104 is illustrated including a vacuum source 224. Vacuum source 224 is configured to pull a vacuum in vacuum chamber 104. Vacuum source 224 is configured to seal cover 108 against body portion 106 when cover 108 is in a “closed position”. Body portion 106 defines a groove 106a configured to receive sealing structure 114 for creating a seal between cover 108 and body portion 106. Although groove 106a is illustrated as generally rectangular, it should be understood that groove 106a may include chamfers, fillets, curved surfaces, and/or other features to receive sealing structure 114 and form a vacuum seal. Body portion 106 defines cooling channel 116 configured to receive a cooling fluid for cooling groove 106a, and consequently cooling sealing structure 114 when disposed within groove 106a. Accordingly, sealing structure 114 can be maintained at a lower temperature than would be possible without cooling channel 116. Thus, less heat-resistant sealing structures (e.g., inexpensive O-rings) can be used in certain applications.

Vacuum source 224 includes elements to provide a vacuum to treat workpiece 102. Vacuum source 224 is illustrated including a pump 224a, a filter 224b, and a valve 224c (e.g., a ball valve) fluidically connected to vacuum chamber 104. A vacuum may be provided by vacuum source 224 to remove voids (e.g., air bubbles) associated with conductive joint formation. In certain embodiments, workpiece 102 (e.g., including a plurality of semiconductor elements 102a) may be supported by heat plate 112 (which is illustrated in FIG. 2 as being supported by a plurality of heat plate mounts 112a, where heat plate mounts 112a are configured to keep heat plate 112 thermally isolated from cooling channel 116) to assist in the removal of voids (e.g., air bubbles) associated with conductive joint formation. In one example, when cover 108 is in a “closed” position, pump 224a may pull a vacuum within vacuum chamber 104 through an outflow channel 226, thereby creating a low enough pressure in the vacuum chamber to allow the voids in the solder layer to expand to reach the edge of the solder layer, that way removing gas bubbles/voids formed in a solder paste used to connect semiconductor elements 102a with a portion of workpiece 102.

Vacuum chamber 104 includes (or is fluidically connected to) a nitrogen supply 228. Nitrogen supply 228 may be used to provide a nitrogen backfill to vacuum chamber 104 through an inflow channel 230. Other gases, such as a different inert gas, or an active gas mixture such as a nitrogen hydrogen mix (e.g., with a hydrogen content not exceeding 5.7%), may be utilized.

Cooling body portion 106 may result in a relatively low temperature of certain surfaces of vacuum chamber 104. Fumes extracted from solder (e.g., solder used to connect semiconductor element 102a to portions of workpiece 102) by using vacuum source 224 may condensate in vacuum chamber 104. Consequently, liquid flux residue may accumulate inside vacuum chamber 104. Depending on the viscosity of the residue, the residue may flow to the bottom of vacuum chamber 104. In certain applications, there is a temperature window in which the viscosity of the liquid flux is low and the flux flows similar to a Newtonian fluid (e.g., ‘like water’), where there may be no measurable evaporation. In certain applications, this range may be between 80° C. to 120° C., which is also low enough to enable using general purpose or low-cost O-rings.

Staying liquid with a relatively low viscosity allows the liquid flux residue to be drained from vacuum chamber 104 in regular intervals, instead of having to open vacuum chamber 104 to remove the liquid flux (e.g., by manual removal or the like). Accordingly, certain embodiments of the invention can reduce time-consuming maintenance work, thereby enabling higher uptime of an oven system.

Referring to FIG. 2, vacuum chamber 104 includes a flux removal system 232 for removing flux from vacuum chamber 104. In certain applications, as voids (e.g., air bubbles) associated with conductive joint formation are removed from the connections between semiconductor elements 102a and portions of workpiece 102, flux may evaporate from such connections. Flux may then condensate within vacuum chamber 104. For example, flux may condensate around an area near cooling channel 116, due to a lower temperature of body portion 106 adjacent cooling channel 116. In such an example, liquid flux may collect in a collection region 106b1 on a lower surface 106b of body portion 106. Accordingly, in certain embodiments, flux removal system 232 may be disposed along a lower surface 106b of body portion 106 to collect liquid flux. In certain embodiments, flux removal system 232 can be used in connection with collection region 106b1 defined by body portion 106, where collection region 106b1 is configured for collecting the flux to be removed from vacuum chamber 104. Although lower surface 106b and collection region 106b1 are illustrated as “flat” along the Y-axis (and/or the X-axis), it should be understood that portions of lower surface 106b and/or collection region 106b1 can be angled or slanted in order to improve liquid flux collection.

In certain embodiments, flux removal system 232 includes an aperture 232a for draining the flux from vacuum chamber 104, and a valve 232b for selectively allowing the flux to pass through aperture 232a. Flux removal system 232 may be used in connection with a thermocouple 234 for sensing temperature. Flux needs to be held at a specific temperature and pressure range to maintain a liquid state without outgassing (e.g., 80-120° C.). Accordingly, in certain embodiments, during operation of flux removal system 232, at least a part of body portion 106 is held at a temperature which keeps the flux in a liquid state. In certain embodiments, at least a part of body portion 106 (e.g., collection region 106b1) is held between 80-120° C.

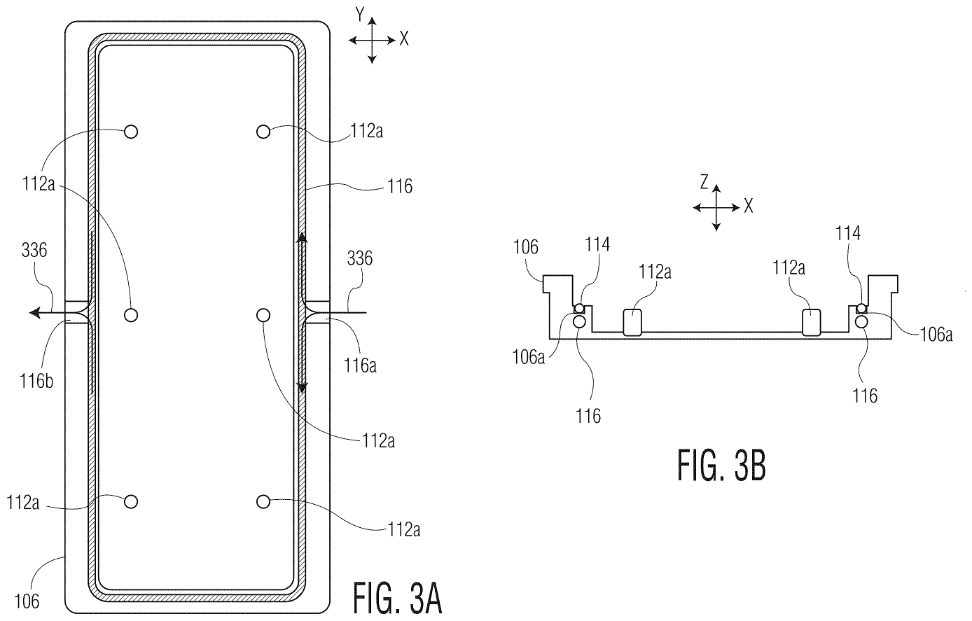

Referring now to FIGS. 3A-3B, a cooling fluid 336 is illustrated being circulated along cooling channel 116. As illustrated, cooling channel 116 is disposed along a path adjacent groove 106a. The path illustrated includes a loop shape, an inlet path 116a connected to the loop shape, and an outlet path 116b connected to the loop shape. Cooling fluid 336 may be embodied as a variety of liquids, such as water, refrigerant, oil, coolant, air, or any fluid with a heat capacity to sufficiently remove heat from body portion 106 and/or sealing structure 114. While FIGS. 3A-3B illustrate the flow of cooling fluid 336 from right to left, it is understood that the flow direction may be altered (e.g., left to right). The flow direction may be selected, for example, in an effort to maintain a more uniform temperature (e.g., the flow direction may be selected depending on which side of the body portion is adjacent a higher versus a lower temperature zone of the oven). It is understood that the plurality of heat plate mounts 112a may be disposed within a plurality of corresponding holes.

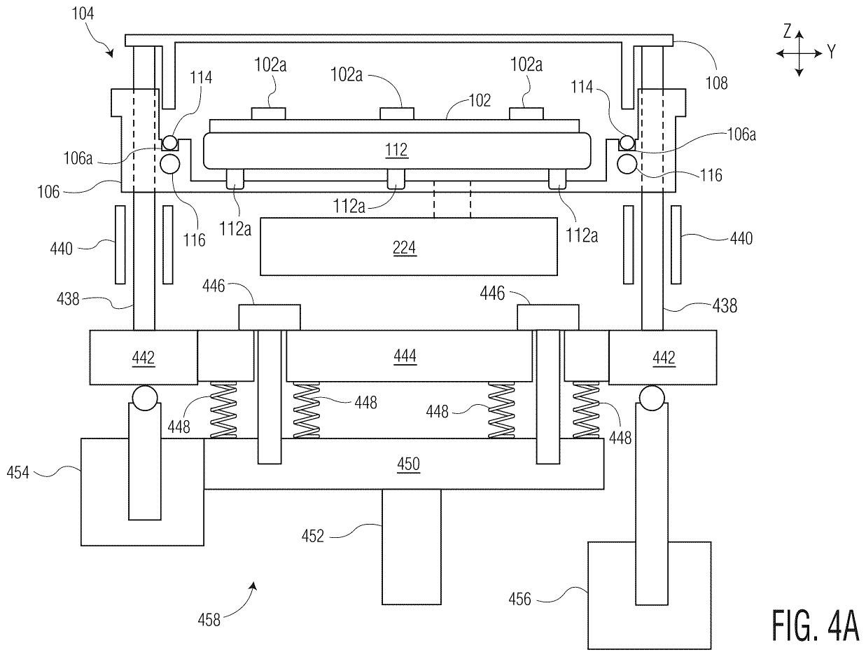

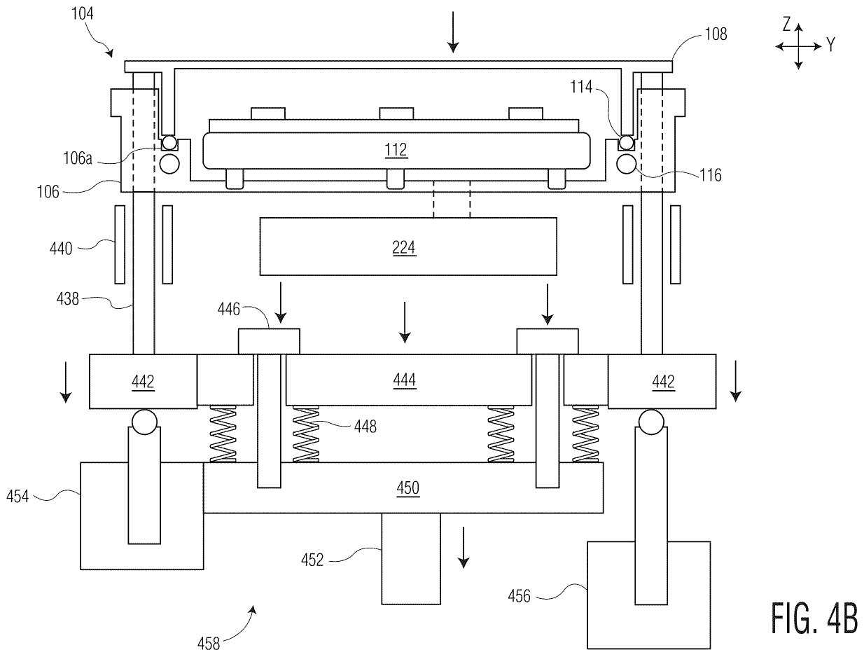

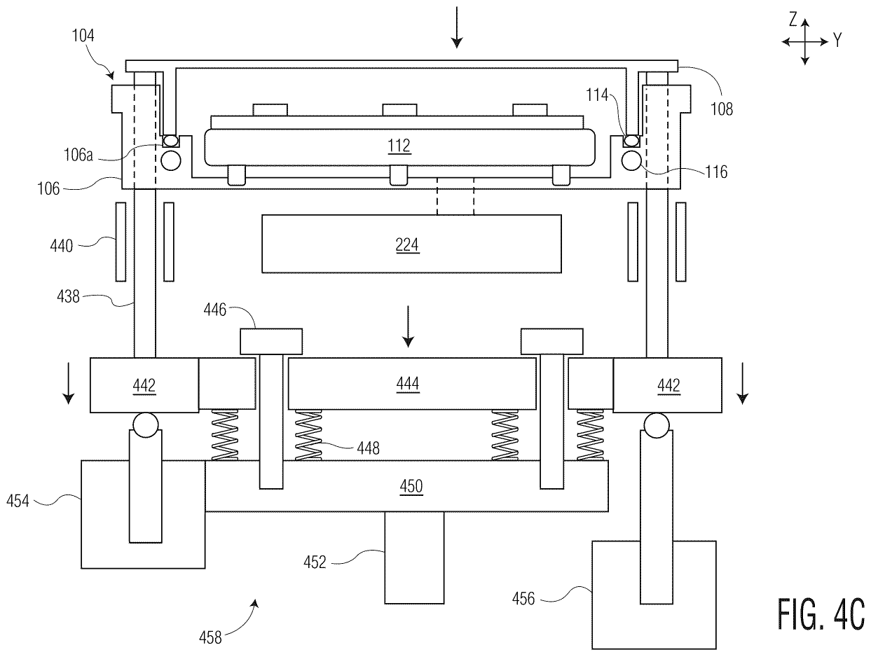

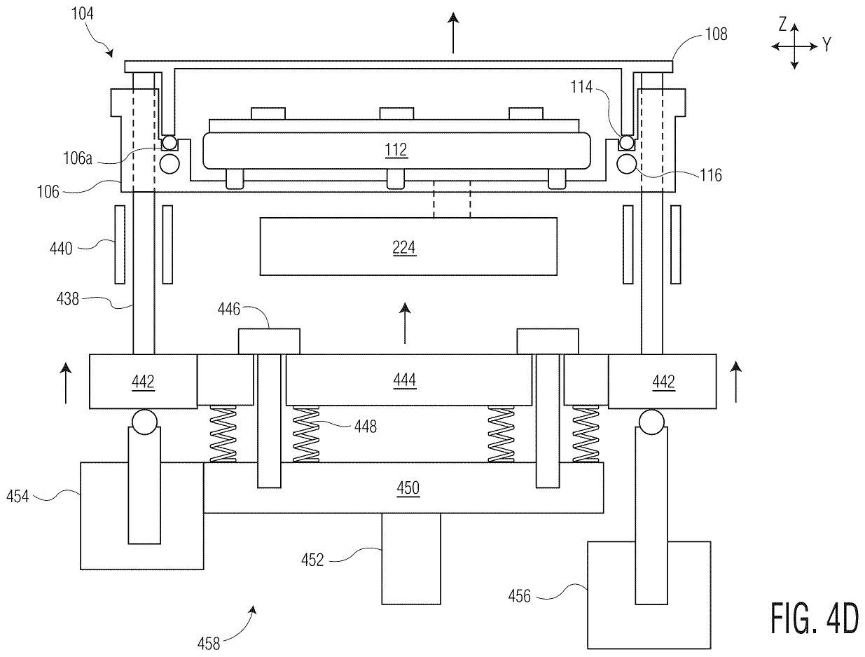

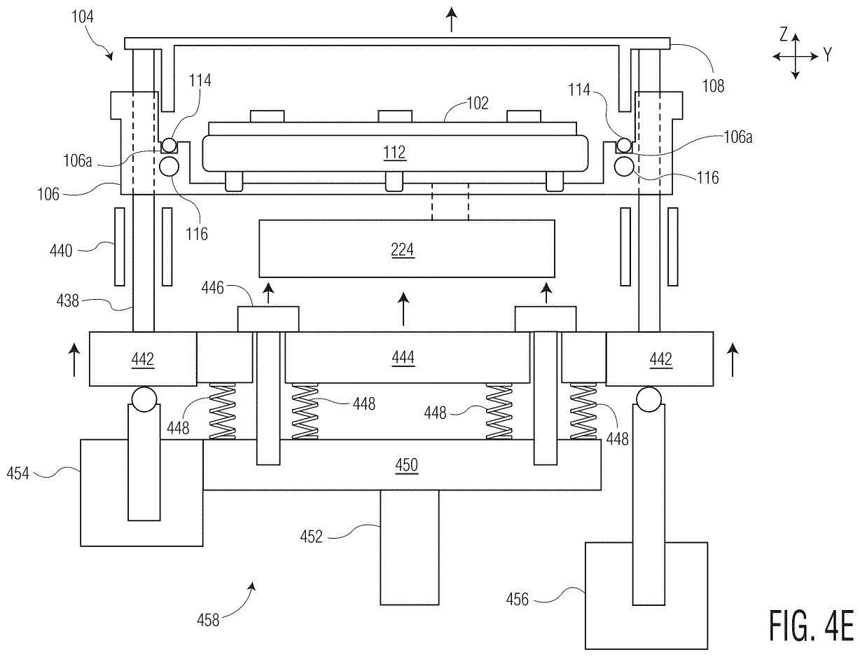

Referring now to FIGS. 4A-4E, various portions of oven 100, including a motion system 458, are illustrated. When opening and closing vacuum cover 108, there are several mechanisms at work which need to be controlled and coordinated carefully to enable robust and repeatable operation such as proper sealing. In a high temperature environment, dimensions or distances of motion system 458 can change due to material dependent thermal expansion behaviors. Relatedly, temperatures must be variable to support a range of reflow processes for a range of solder materials/alloys. Associated operational problems may be solved by using a motor 452 (e.g., a servo motor) to move cover 108 of vacuum chamber 104 from an open position down onto sealing structure 114 (e.g., an O-ring), positioning a sealing surface of vacuum cover 108 sufficiently close to a top surface of sealing structure 114. After such positioning, vacuum source 224 (including vacuum pump 224a) may be switched on (e.g., including using valve 224c of FIG. 2) to pump down vacuum chamber 104. Vacuum source 224 may have sufficient flow capacity to overcome any minor leaks from a limited contact between sealing structure 114 and a sealing surface of cover 108. In order to not be affected by motor 452, cover 108 is positioned/mounted in a “floating” configuration such that the vacuum provided by vacuum source 224 can pull cover 108 down onto sealing structure 114 to achieve sufficient/improved sealing while motor 452 is set to a “closed” position. In certain embodiments, there is a distance range that may be considered “sufficiently close” to consistently enable reliable vacuum chamber 104 closure and vacuum creation, without having to move cover 108 down to an exact position. Cover 108 desirably moves down sufficiently to minimize leaks. Otherwise, when vacuum pump 224a starts pulling the vacuum there may be large leaks, whereby vacuum pump 224a may pull gas from the oven chamber (the oven chamber being at least partially defined by oven plate 103 and oven cover 110). Worse still, vacuum pump 224a could pull air through the oven chamber entrance and exit, causing oxidation of workpieces 102 (e.g., lead frames) in the oven chamber. The floating structure allows motor 452 to move lower beyond the point where cover 108 touches sealing structure 114, not requiring an exact ‘closed position’, but guaranteeing that cover 108 always touches sealing structure 114.

In certain embodiments, when opening vacuum chamber 104, pre-heated nitrogen (or other gas such as a different inert gas, or an active gas mixture such as a nitrogen hydrogen mix (e.g., with a hydrogen content not exceeding 5.7%)) may be injected into vacuum chamber 104 at a controllable rate to increase the chamber pressure from “vacuum” to (or very close to) ambient pressure. The pressure in vacuum chamber 104 may be continuously measured (e.g., by a pressure sensor, not shown). Once the chamber pressure reaches a defined level close enough to ambient pressure, motor 452 may move cover 108 at a controlled low speed for a short distance to gently disengage cover 108 from sealing structure 114. Motor 452 may then change to a faster speed to move to an upper position (e.g., thereby mitigating unproductive oven cycle time).

Distance sensors and/or position sensors may be used to independently measure the Z position of cover 108 as well as a “floating” position of cover 108. Such sensors may be used to observe changes to the Z stroke behavior of cover 108 (and/or associated components of motion system 458). Specifically, the “floating” position may be sensitive to friction (e.g., changes to friction) in the mechanical structure that moves the vacuum cover. Changes in Z stroke behavior can be caused by changes of the alignment, for example, due to temperature changes, or surfaces becoming covered by process residues, or surface wear. Such changes can potentially lead to operational problems (e.g., malfunction of the Z-stroke mechanism), which may cause a jam of certain components of motion system 458, which could interrupt the continuous flow of workpieces (e.g., lead frames) through oven 100, change processing conditions, cause parts in oven 100 to be damaged, cause yield loss, among other problems. As such the “floating” position is monitored and observed changes in behavior may be used to trigger maintenance checks and/or warnings to avoid a yield loss event. As the floating position data is continuously recorded and the data stored, the data can be analyzed and used to create a predictive maintenance scheme, for example, using machine learning methods.

Referring specifically to FIG. 4A, vacuum chamber 104 and/or cover 108 are illustrated in an open position. Motion system 458 is illustrated and is configured to move cover 108 with respect to body portion 106 between an open position and a closed position. Motor 452 has driven cover 108 up (i.e., along the Z-axis) and vacuum chamber 104 is not pulling a vacuum (e.g., via vacuum source 224). Cover 108 is operably/mechanically coupled to a plurality of rods 438. Each of the plurality of rods 438 are disposed within an alignment structure 440 (e.g., a bushing) to move cover 108 in a controlled manner (e.g., with minimal friction). Each of the plurality of rods 438 are connected to a movable structure 444 (e.g., a plate) via a thermal expansion structure 442. Such thermal expansion structures 442 provide for compliance, for example, along the X-axis and/or Y-axis. That is, the plurality of rods 438 may be configured to move in different directions via their respective thermal expansion structure 442 in order to provide compliance as vacuum chamber 104 and other structures of oven 100 change in temperature (e.g., from room temperature to elevated temperatures, such as 450° C.). In other words, while rods 438 primarily move along the Z-axis, rods 438 may be able to move along the Y-axis and/or X-axis (e.g., to a small degree) in order to prevent mechanical lockup associated with thermal expansion from oven 100. Movable structure 444 is illustrated connected to a structure 450 and a motor 452 via a plurality of connecting structures 446 (e.g., bolts, screws, rods, etc.) and a plurality of springs 448. It should be understood that the configuration of elements in the drawings (including in FIGS. 4A-4E) are exemplary in nature, and different configurations are contemplated. For example, one or more springs (e.g., replacing the plurality of springs 448) may be placed in different locations than illustrated in FIGS. 4A-4E. In a specific example, such springs may be placed between (i) a head portion of the connecting structures 446 (e.g., underneath the head of a bolt-like structure) and (ii) a top surface of movable structure 444, such that different kinematics of the system are achievable (e.g., absorbing overtravel commands from motor 452).

Referring now to FIG. 4B, cover 108 has been lowered via motion system 458 (including the plurality of rods 438 and motor 452) such that a portion of cover 108 is brought into contact with sealing structure 114. Cover 108 has been moved due to a motor 452 of motion system 458 moving (e.g., indirectly) cover 108. Vacuum chamber 104 and/or cover 108 may be considered to be in a “closed” position. In this configuration, vacuum chamber 104 may not be pulling a vacuum (e.g., via vacuum source 224) and thus a vacuum seal may not be fully formed.

Referring now to FIG. 4C, vacuum chamber 104 is illustrated in a closed position. In a closed position, when vacuum source 224 pulls the vacuum in vacuum chamber 104, cover 108 moves closer to body portion 106 (i.e., along the Z-axis) for sealing cover 108 against body portion 106. Thus, vacuum source 224 seals (e.g., vacuum seals) cover 108 against body portion 106 when cover 108 is in the closed position. As illustrated, sealing structure 114 is deformed as cover 108 is moved into a sealed position. It should be understood that although sealing structure 114 is illustrated as an O-ring disposed within groove 106a, the invention is not so limited. In certain embodiments, sealing structure 114 may be another type of gasket, etc. Through the operation of vacuum source 224, sealing structure 114 compresses and moves cover 108 between a range of 0.2-2.0 mm (of course, in certain embodiments cover 108 may not be moved, and sealing structure 114 may not be compressed, through the operation of vacuum source 224). As cover 108 moves down, movable structure 444 is moved down from the plurality of rods 438, thereby engaging and compressing springs 448.

Cover 108 may have a range of motion between the open position (e.g., see FIG. 4A) and the closed position (e.g., see FIG. 4C) of between 10-200 mm. It should be understood that a position sensor 454 (e.g., a linear variable differential transformer or “LVDT”, or other measurement devices such as encoders) and a position sensor 456 (e.g., a LVDT, an encoder, etc.) can be used to measure the displacements (e.g., a travel distance) of certain components of motion system 458, such as the plurality of rods 438, thermal expansion structure 442, movable structure 444, cover 108 (e.g., indirectly or directly measured), among others. In certain embodiments, position sensor 454 (e.g., an LVDT) may measure the relative movement (e.g., along a direction of travel, along the Z-axis, etc.) of cover 108 (and/or associated/connected structures) as a vacuum is pulled and/or sealing structure 114 is compressed. In certain embodiments, position sensor 456 (e.g., an LVDT) may measure the overall movement of cover 108 (and/or associated/connected structures) as motor 452 commands various positions (e.g., along a direction of travel, along the Z-axis, etc.); that is, position sensor 456 measures movement of cover 108 caused by motor 452 and movement caused by the application of vacuum.

Referring now to FIG. 4D, vacuum source 224 has been turned off and springs 448 restore cover 108 to the position of FIG. 4B. Thus, springs 448 may move cover 108 without needing to engage motor 452. In certain embodiments, nitrogen (e.g., heated nitrogen) may be injected into vacuum chamber 104 by a nitrogen supply (not illustrated) in connection with turning off vacuum source 224, for example, to increase the pressure to ambient.

Referring now to FIG. 4E, motion system 458 has moved cover 108 back to the position of FIG. 4A using motor 452 and the plurality of rods 438. Thus, vacuum chamber 104 is illustrated in an “open” position.

Vacuum chamber 104 may be operated in a plurality of modes (e.g., two distinct modes). In a first mode, vacuum pump 224a is continuously on while a vacuum command is provided during the cycle, and then vacuum pump 224a is switched off when vacuum chamber 104 shall be backfilled and nitrogen is injected. In a second mode, vacuum pump 224a is switched off and valve 224c is closed once a target vacuum level is reached. This second mode may be considered the normal operating mode. An additional mode is to perform more than one vacuum cycle (for example two); in such a mode, one may close vacuum chamber 104, pump down, dwell at minimum pressure, backfill pump down, dwell at minimum pressure, backfill, and open vacuum chamber 104 (e.g., between two index steps of the workpiece, such as a lead frame), to simulate a double vacuum chamber process with a single vacuum chamber oven version.

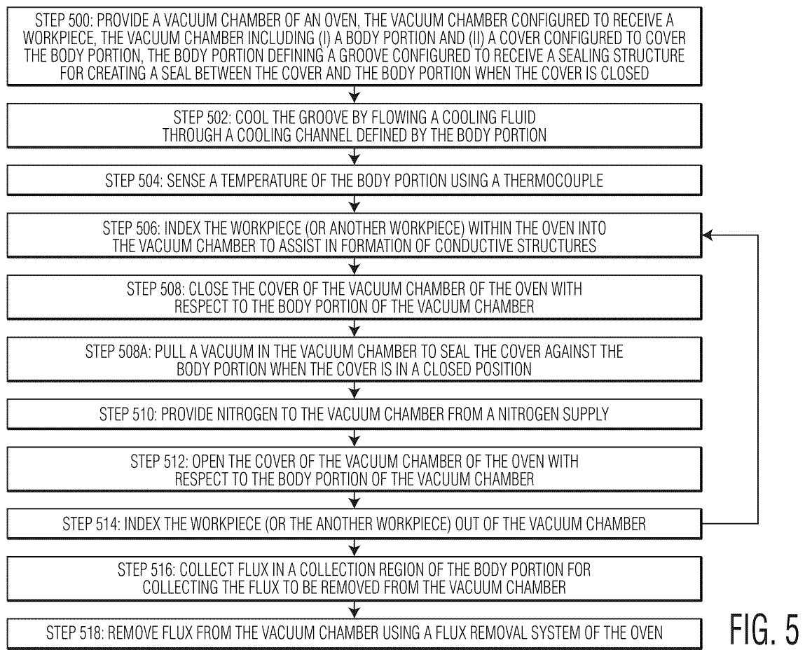

FIG. 5 is a flow diagram illustrating various methods of operating an oven for assisting in conductive joint formation related to a workpiece. As is understood by those skilled in the art, certain steps included in the flow diagram may be omitted; certain additional steps may be added; and the order of the steps may be altered from the order illustrated—all within the scope of the invention.

At Step 500, a vacuum chamber (e.g., vacuum chamber 104) of an oven (e.g., oven 100) is provided. The vacuum chamber is configured to receive a workpiece. The vacuum chamber includes (i) a body portion (e.g., body portion 106) and (ii) a cover (e.g., cover 108) configured to cover the body portion. The body portion defines a groove (e.g., groove 106a) configured to receive a sealing structure (e.g., sealing structure 114) for creating a seal between the cover and the body portion when the cover is closed. At Step 502, the groove is cooled by flowing a cooling fluid (e.g., water, air) through a cooling channel (e.g., cooling channel 116) defined by the body portion. At Step 504, a temperature of the body portion is sensed using a thermocouple (e.g., thermocouple 234) (or another temperature measuring device, such as an RTD or IR camera). The temperature measurement may be used, for example, in connection with the control of the temperature of the body portion (e.g., by cooling with the cooling fluid). At Step 506, the workpiece is indexed within the oven into the vacuum chamber to assist in formation of conductive structures. At Step 508, the cover of the vacuum chamber of the oven is closed with respect to the body portion of the vacuum chamber (e.g., see FIG. 4B). In certain embodiments, at Step 508A, a vacuum is pulled in the vacuum chamber to seal the cover against the body portion when the cover is in a closed position (e.g., see FIG. 4C). At Step 510, nitrogen is provided to the vacuum chamber from a nitrogen supply (e.g., see nitrogen supply 228) (other gases, such as a different inert gas, or an active gas mixture such as a nitrogen hydrogen mix, may be utilized), such that the vacuum may be shut off and the cover may be opened. At Step 512, the cover of the vacuum chamber of the oven is opened with respect to the body portion of the vacuum chamber (e.g., see FIGS. 4D-4E). At Step 514, the workpiece is indexed out of the vacuum chamber. In certain embodiments, another workpiece is indexed into the vacuum chamber (e.g., Step 506-514 are repeated). At Step 516, flux is collected in a collection region (e.g., see collection region 106b1) of the body portion for collecting the flux to be removed from the vacuum chamber (e.g., in Step 518). At Step 518, flux is removed from the vacuum chamber using a flux removal system (e.g., see flux removal system 232) of the oven.

It should be understood that one or more of the steps described in connection with FIG. 5 can be repeated cyclically or implemented continuously. For example, Steps 500-504 and Steps 516-518 may be implemented continuously during operation of the oven. It should also be understood that heat sufficient to operate the oven may be provided (e.g., via heat plate 112) throughout the various steps.

Although the invention has been illustrated and described primarily with reference to an oven including a single vacuum chamber, the invention is not limited to such embodiments. For example, the invention may be implemented in connection with an oven having a plurality of vacuum chambers (e.g., two vacuum chambers).

Although the invention is illustrated and described herein with reference to specific embodiments, the invention is not intended to be limited to the details shown. Rather, various modifications may be made in the details within the scope and range of equivalents of the claims and without departing from the invention.

Claimed:

1. An oven for assisting in conductive joint formation related to a workpiece, the oven comprising:
a vacuum chamber, the vacuum chamber configured to receive the workpiece, the vacuum chamber including (i) a body portion and (ii) a cover configured to cover the body portion,
the body portion defining a groove configured to receive a sealing structure for creating a seal between the cover and the body portion, the body portion defining a cooling channel configured to receive a cooling fluid for cooling the groove.

2. The oven of claim 1 wherein the sealing structure is a gasket.

3. The oven of claim 1 wherein the body portion is configured to be removed from the oven.

4. The oven of claim 1 wherein the body portion is a removable insert.

5. The oven of claim 1 wherein the body portion includes a heat plate for heating the workpiece.

6. The oven of claim 1 further comprising a motor operably coupled to the cover, the cover being configured to be moved in at least one direction by the motor.

7. The oven of claim 6 wherein the motor is configured to move the cover in the at least one direction between a closed position and an open position.

8. The oven of claim 7 further comprising a vacuum source configured to pull a vacuum in the vacuum chamber when the cover is in the closed position, wherein the vacuum in the vacuum chamber results in the cover moving further downward from the closed position.

9. The oven of claim 1 wherein the cooling channel is disposed along a path adjacent the groove.

10. The oven of claim 9 wherein the path includes a loop shape, an inlet path connected to the loop shape, and an outlet path connected to the loop shape.

11. The oven of claim 1 further comprising an oven chamber, the vacuum chamber being positioned within the oven chamber, the oven chamber being at least partially defined by (i) an oven plate and (ii) an oven cover.

12. An oven for assisting in conductive joint formation related to a workpiece, the oven comprising:
a vacuum chamber, the vacuum chamber configured to receive the workpiece, the vacuum chamber including (i) a body portion and (ii) a cover configured to cover the body portion;
a motion system configured to move the cover with respect to the body portion between an open position and a closed position; and
a vacuum source configured to pull a vacuum in the vacuum chamber, the vacuum source sealing the cover against the body portion when the cover is in the closed position.

13. The oven of claim 12 wherein in the closed position, when the vacuum source pulls the vacuum, the cover moves closer to the body portion for sealing the cover against the body portion.

14. The oven of claim 13 wherein the body portion defines a groove configured to receive a sealing structure for creating a seal between the cover and the body portion,
wherein when the vacuum source pulls a vacuum to form the seal, the sealing structure compresses and moves the cover between a range of 0.2-2.0 mm.

15. The oven of claim 12 wherein the motion system includes a plurality of rods coupled to the cover.

16. The oven of claim 15 wherein the motion system includes thermal expansion structures coupled to each of the plurality of rods.

17. The oven of claim 12 wherein the cover has a range of motion between the open position and the closed position of between 10-200 mm.

18. An oven for assisting in conductive joint formation related to a workpiece, the oven comprising:
a vacuum chamber, the vacuum chamber configured to receive the workpiece, the vacuum chamber including (i) a body portion and (ii) a cover configured to cover the body portion; and
a flux removal system for removing flux from the vacuum chamber.

19. The oven of claim 18 wherein the flux removal system is disposed along a lower surface of the body portion.

20. The oven of claim 18 wherein the flux removal system includes an aperture for draining the flux from the vacuum chamber, and a valve for selectively allowing the flux to pass through the aperture.

21.-48. (canceled)
